(19) United States
(12) Patent Application Publication
(10) Pub. No.: US 2024/0388059 A1
(43) Pub. Date: Nov. 21, 2024

(54) PHOTONIC CRYSTAL LASER DEVICE AND METHOD FOR MANUFACTURING THE SAME

(71) Applicant: SEOUL NATIONAL UNIVERSITY R&DB FOUNDATION, Seoul (KR)

(72) Inventors: Heonsu JEON, Gwacheon-si (KR); Myeongeun KIM, Bucheon-si (KR)

(73) Assignee: SEOUL NATIONAL UNIVERSITY R&DB FOUNDATION, Seoul (KR)

(21) Appl. No.: 18/662,489

(22) Filed: May 13, 2024

(30) Foreign Application Priority Data
May 18, 2023 (KR) 10-2023-0064639
Jan. 24, 2024 (KR) 10-2024-0010586

(51) Int. Cl. H01S 5/11; H01S 5/02; H01S 5/042; H01S 5/20; H01S 5/32

(52) U.S. Cl. CPC H01S 5/11; H01S 5/0215; H01S 5/0217; H01S 5/0421; H01S 5/04256; H01S 5/2018; H01S 5/3211

(57) ABSTRACT

Provided is a photonic crystal laser device including a lower electrode layer on a top surface or bottom surface of a substrate, a guide layer on the lower electrode layer, an upper electrode layer on the guide layer, a lower clad layer between the lower electrode layer and the guide layer, and an upper clad layer between the guide layer and the upper electrode layer. The guide layer includes an active layer therein. A crystal hole is provided that penetrates the upper clad layer in a vertical direction and extends toward the guide layer. A lower end of the crystal hole is defined to be at a height higher than or at the same height as a top surface of the active layer.

### CROSS-REFERENCE TO RELATED APPLICATIONS

This U.S. non-provisional patent application claims priority under 35 U.S.C. § 119 of Korean Patent Application Nos. 10-2023-0064639, filed on May 18, 2023, and 10-2024-0010586, filed on Jan. 24, 2024 the entire contents of which are hereby incorporated by reference.

### BACKGROUND

The present disclosure herein relates to a photonic crystal laser device, and more specifically, to a photonic crystal laser device including crystal holes as a two-dimensional photonic crystal pattern.

This research was conducted with support from the Samsung Future Technology Promotion Project (Project Number: SRFC-MA1801-02).

A photonic crystal refers to a structure in which two materials with different refractive indices are arranged periodically on a scale about a wavelength of light. Representative characteristics of photonic crystals include a photonic bandgap, strong nonlinearity, and dispersion characteristics. One of photonic crystal devices that utilizes these characteristics is a photonic crystal laser device, which is a type of semiconductor laser device.

The photonic crystal laser device is a laser structure that may not only provide a variety of functionality including single-mode oscillation or laser emission perpendicular to a substrate, but may also dramatically reduce a size of an existing semiconductor laser device.

However, in the case of photonic crystal laser device, electrical driving is very difficult and limited due to structural constraints. In particular, the photonic crystal laser device should include a fine structure that functions as the photonic crystal pattern required for laser oscillation. Accordingly, research to develop the photonic crystal laser device that satisfies the laser oscillation characteristics and at the same time facilitates a manufacturing process of the fine structure is being actively conducted.

### SUMMARY

The present disclosure provides a photonic crystal laser device with excellent laser oscillation characteristics.

The limitation to be solved by an embodiment of the inventive concept is not limited to the limitation mentioned above, and other limitations not mentioned can be clearly understood by those skilled in the art from the description below.

An embodiment of the inventive concept provides a photonic crystal laser device including a lower electrode layer on a top surface or bottom surface of a substrate, a guide layer on the lower electrode layer, an upper electrode layer on the guide layer, a lower clad layer between the lower electrode layer and the guide layer, and an upper clad layer between the guide layer and the upper electrode layer. The guide layer includes an active layer therein. A crystal hole is provided that penetrates the upper clad layer in a vertical direction and extends toward the guide layer. A lower end of the crystal hole is formed to be at a height higher than or at the same height as a top surface of the active layer.

In an embodiment of the inventive concept, a method for manufacturing a photonic crystal laser device includes sequentially forming a lower clad layer, a guide layer, and an upper clad layer on a substrate, and forming a crystal hole that penetrates the upper clad layer in a vertical direction and extends toward the guide layer. The guide layer includes an active layer therein. A lower end of the crystal hole is formed at a height higher than or at the same height as a top surface of the active layer.

In an embodiment of the inventive concept, a method for manufacturing a photonic crystal laser device includes sequentially stacking an upper clad layer, a guide layer, and a lower clad layer on an auxiliary substrate, bonding a stacked structure onto a substrate by turning the stacked structure on the auxiliary substrate upside down, removing the auxiliary substrate, and forming a crystal hole that penetrates the upper clad layer in a vertical direction and extends toward the guide layer. The guide layer includes an active layer therein. A lower end of the crystal hole is formed at a height higher than or at the same height as a top surface of the active layer.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept.

In the drawings:

FIG. 1 is a cross-sectional view illustrating a photonic crystal laser device according to an embodiment of the inventive concept;

FIG. 2 is a cross-sectional view illustrating a guide layer of a photonic crystal laser device according to an embodiment of the inventive concept;

FIG. 3 is a graph illustrating a refractive index according to a height in the photonic crystal laser device including the guide layer according to FIG. 2;

FIG. 4 is a graph illustrating intensity of an optical field according to height in the photonic crystal laser device including the guide layer according to FIG. 2;

FIG. 5 is a graph illustrating an overlap factor according to a depth of a crystal hole in a photonic crystal laser device according to an embodiment of the inventive concept;

FIG. 6 is a cross-sectional view illustrating a photonic crystal laser device according to an embodiment of the inventive concept;

FIG. 7 is a cross-sectional view illustrating a photonic crystal laser device according to an embodiment of the inventive concept;

FIG. 8 is a cross-sectional view illustrating a photonic crystal laser device according to an embodiment of the inventive concept;

FIG. 9 is a cross-sectional view illustrating a method for manufacturing a photonic crystal laser device according to an embodiment of the inventive concept;

and

FIG. 10 is a cross-sectional view illustrating a method for manufacturing a photonic crystal laser device according to an embodiment of the inventive concept.

### DETAILED DESCRIPTION

Embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

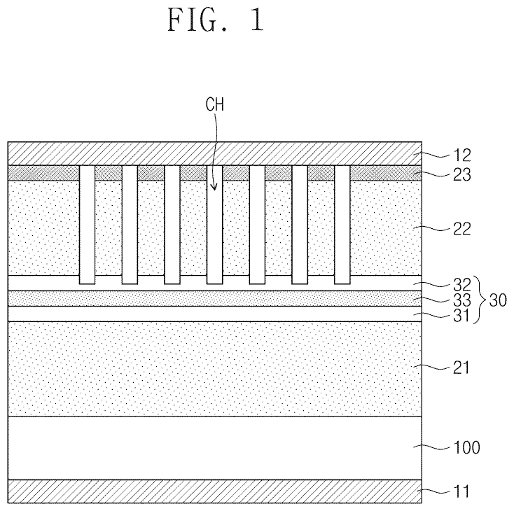

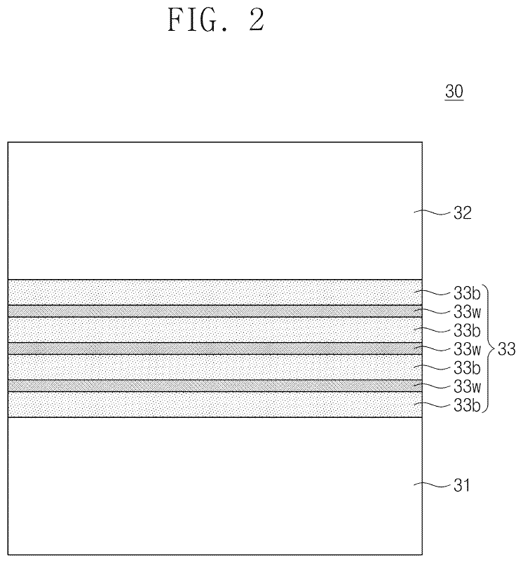

FIG. 1 is a cross-sectional view illustrating a photonic crystal laser device according to an embodiment of the inventive concept. FIG. 2 is a cross-sectional view illustrating a guide layer of the photonic crystal laser device according to the embodiment of the inventive concept.

Referring to FIGS. 1 and 2, a substrate 100 may be provided. The substrate 100 may contain a group III-V compound semiconductor material. As an example, the substrate 100 may be made of indium phosphorus (InP), but is not limited thereto.

A lower clad layer 21, a guide layer 30, and an upper clad layer 22 may be sequentially provided on the substrate 100. Hereinafter, the vertical direction is defined as a direction in which the layers are stacked, and the horizontal direction is defined as a direction in which top surfaces or bottom surfaces of the layers extend. As an example, the guide layer 30 may be in contact with a top surface of the lower clad layer 21 and a bottom surface of the upper clad layer 22.

The guide layer 30 may include a lower guide layer 31, an active layer 33, and an upper guide layer 32 that are sequentially stacked. The lower guide layer 31 may be interposed between the active layer 33 and the lower clad layer 21, and may be in contact with the top surface of the lower clad layer 21. The upper guide layer 32 may be interposed between the active layer 33 and the upper clad layer 22, and may be in contact with the bottom surface of the upper clad layer 32.

Each of the lower clad layer 21, the guide layer 30, and the upper clad layer 22 may contain a group III-V compound semiconductor material. As an example, each of the lower clad layer 21 and the upper clad layer 22 may contain InP, and the guide layer 30 may contain at least one of indium gallium arsenide (InGaAsP) or indium gallium arsenide (InGaAs).

The lower clad layer 21 and the upper clad layer 22 may further contain different types of dopants. As an example, the lower clad layer 21 may be an n-type clad layer containing an n-type dopant, and the upper clad layer 22 may be a p-type clad layer containing a p-type dopant. As another example, the lower clad layer 21 may be the p-type clad layer containing the p-type dopant, and the upper clad layer 22 may be the n-type clad layer containing the n-type dopant.

The lower guide layer 31 and the upper guide layer 33 may further contain different types of dopants. The lower guide layer 31 may further contain a dopant of the same type as that of the lower clad layer 21, and the upper guide layer 32 may further contain a dopant of the same type as that of the upper clad layer 22. As an example, the lower guide layer 31 may be InGaAsP containing the n-type dopant, and the upper guide layer 32 may be InGaAsP containing the p-type dopant. As another example, the lower guide layer 31 may be InGaAsP containing the p-type dopant, and the upper guide layer 32 may be InGaAsP containing the n-type dopant.

The active layer 33 may have a single quantum well (SQW) or multi-quantum well (MQW) structure. For example, as illustrated in FIG. 2, the active layer 33 may have the MQW structure including four layers of barriers 33b and three layers of quantum wells 33w interposed between the barriers. As an example, the barrier 33b may be made of InGaAsP, and the quantum well 33w may be made of InGaAs, but are not limited thereto.

The lower electrode layer 11 may be provided below the lower clad layer 21. For example, as illustrated in FIG. 1, the lower electrode layer 11 may be provided on the bottom surface of the substrate 100, and may be spaced apart from the lower clad layer 21 with the substrate 100 interposed therebetween. However, the embodiment of the inventive concept is not limited thereto. An upper electrode layer 12 may be provided above the upper clad layer 22. For example, as illustrated in FIG. 1, the upper electrode layer 12 may cover a crystal hole CH, which will be described later, but is not limited thereto. Each of the lower electrode layer 11 and the upper electrode layer 12 may contain a conductive material (e.g., metal, etc.).

A contact layer 23 may be interposed between the lower electrode layer 11 and the lower clad layer 21, or between the upper electrode layer 12 and the upper clad layer 22. As an example, the contact layer 23 may be located adjacent to the p-type clad layer. For example, when the upper clad layer 22 is the p-type clad layer, the contact layer 23 may be interposed between the upper clad layer 22 and the upper electrode layer 12 as illustrated in FIG. 1.

The contact layer 23 may contain a group III-V compound semiconductor material and the p-type dopant. The contact layer 23 may have a higher p-type doping concentration than that of the adjacent p-type clad layer. Current may flow more easily between the adjacent p-type clad layer and the electrode layer through the contact layer 23 having a higher doping concentration. The contact layer 23 may be provided between the p-type clad layer and the electrode layer, which has relatively low charge mobility, but the embodiment of the inventive concept is not limited thereto. As another example, the contact layer 23 may be provided between the n-type clad layer and the electrode layer. In this case, the contact layer 23 may have a higher n-type doping concentration than that of the adjacent n-type clad layer.

The crystal hole CH may penetrate the upper clad layer 22 along the vertical direction. The crystal hole CH may extend from the top surface of the upper clad layer 22 toward the guide layer 30. As an example, the lower end of the crystal hole CH may be formed at a height lower than the top surface of the upper clad layer 22 and higher than or at the same height as the top surface of the active layer 33. For example, when the contact layer 23 is interposed between the upper clad layer 22 and the upper electrode layer 12, the crystal hole CH may further extend from the upper clad layer 22 to the top surface of the contact layer 23.

A plurality of crystal holes CH may be provided. The plurality of crystal holes CH may be arranged to be spaced apart from each other in the horizontal direction on a plane, and may define a two-dimensional photonic crystal pattern. As an example, the plurality of crystal holes CH may be arranged in a hexagonal lattice or honeycomb lattice pattern, but is not limited thereto.

As an example, the inside of the plurality of crystal holes CH may be filled with air, and accordingly, the photonic crystal laser device may include a photonic crystal cavity structure as an artificial defect. As another example, the plurality of crystal holes CH may be filled with a low refractive index material including a solid material, which has a low refractive index, other than air. The low refractive index material may include a material having a lower refractive index than that of a semiconductor layer (e.g., InP) defining the crystal holes CH, such as SiO₂, Al₂O₃, or a polymer.

As an example, the plurality of crystal holes CH may be arranged in a disordered structure, and accordingly, the photonic crystal laser device may include a random laser structure. As an example, the crystal hole CH may be located in a central region of the photonic crystal laser device.

When a voltage is applied through the lower electrode layer 11 and the upper electrode layer 12, electrons and holes that have moved through the lower clad layer 21 and the upper clad layer 22 may be recombined in the active layer 33, and thus light may be generated. The light generated from the active layer 33 may easily form an optical mode in the vertical direction through a stacked structure including the lower clad layer 21, the guide layer 30, and the upper clad layer 22.

If the optical mode defined in the vertical direction meets the two-dimensional photonic crystal pattern defined by the crystal holes CH, a band-edge mode required for laser oscillation may be formed in the horizontal direction. In this case, in order to obtain stronger characteristics of the desired band-edge mode, the arrangement and depth of the crystal holes CH may be adjusted.

As an example, when the crystal hole CH is formed deeply, the optical mode overlaps the two-dimensional photonic crystal pattern in a wider region in the vertical direction. The fact that the optical mode overlaps a lot with the two-dimensional photonic crystal pattern may also be expressed as the fact that the optical mode feels the two-dimensional photonic crystal pattern well. Accordingly, the optical feedback through the crystal hole CH may sufficiently proceed in a wider vertical region, and as a result, the characteristics of the band-edge mode to be obtained are strengthened. However, the deeper the crystal hole CH is formed, the more difficult the manufacturing process becomes.

In contrast, if the crystal hole CH is formed shallowly, the manufacturing process becomes easy, but the optical mode may not sufficiently feel the two-dimensional photonic crystal pattern. Accordingly, the optical feedback becomes insufficient, and the characteristics of the desired band-edge mode may not be sufficiently obtained.

According to the embodiment of the inventive concept, the crystal hole CH is formed deep enough to completely penetrate the upper clad layer 22 and extends to the inside of the upper guide layer 32, and thus the optical mode in the vertical direction may sufficiently feel the two-dimensional photonic crystal pattern in a predetermined vertical region. As a result, the laser oscillation characteristics of the photonic crystal laser device may be improved.

At the same time, the lower end of the crystal hole CH may be defined at a height higher than or at the same height as the top surface of the active layer 33. In this case, compared to the case where the crystal hole CH extends to the inside of the active layer 33, an area of the active layer 33 exposed to the outside may be reduced. Accordingly, when electrons and holes are recombined, heat generated from an exposed surface of the active layer 33 may be reduced, and energy loss due to heat generation may be reduced. As a result, a laser may be efficiently oscillated using relatively little energy, and the laser oscillation characteristics of the photonic crystal laser device may be improved.

Although not illustrated, as an example, the guide layer 30 may further include a current spreading layer. The current spreading layer may be interposed between the lower guide layer 31 and the active layer 33, or between the upper guide layer 32 and the active layer 33. The current spreading layer may spread charges (e.g., electrons) in the horizontal direction. Accordingly, in a planar view, recombination of electrons and holes may easily occur on the entire surface of the active layer 33, and as a result, the laser oscillation characteristics of the photonic crystal laser device may be improved. As an example, the current spreading layer may be InGaAsP containing the n-type dopant.

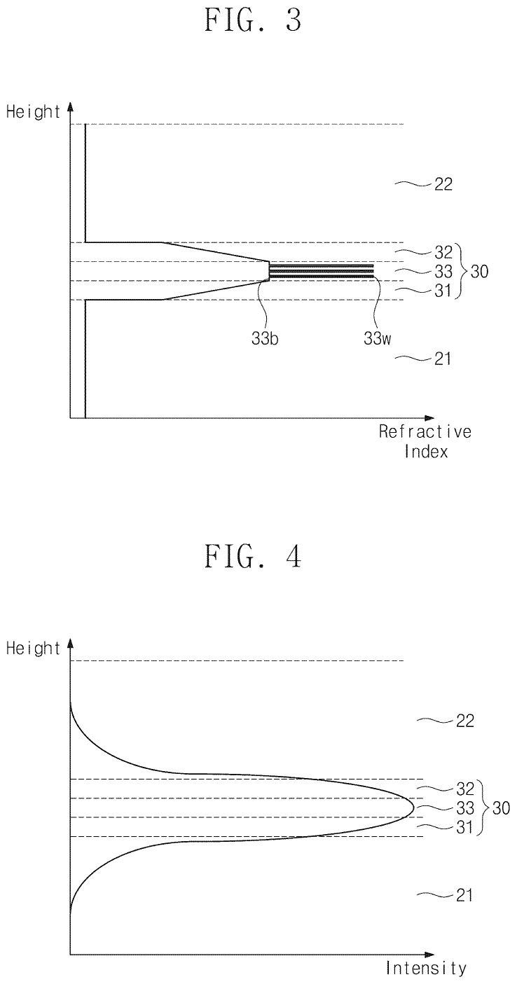

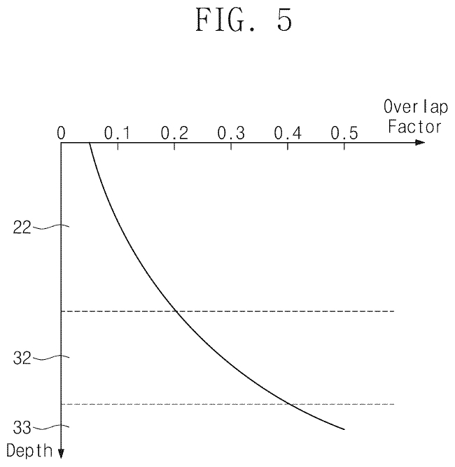

FIG. 3 is a graph illustrating a refractive index according to height in the photonic crystal laser device including the guide layer according to FIG. 2. FIG. 4 is a graph illustrating the intensity of the optical field according to height in the photonic crystal laser device including the guide layer according to FIG. 2.

Referring to FIG. 3, the refractive index of the guide layer 30 may be higher than the refractive index of each of the lower clad layer 21 and the upper clad layer 22. The refractive index of the active layer 33 may be higher than the refractive index of each of the lower guide layer 31 and the upper guide layer 32. As an example, the refractive index of each of the lower guide layer 31 and the upper guide layer 32 may decrease or become uniform as the distance from the active layer 33 increases, but is not limited thereto. The refractive index of the quantum well 33w may be higher than the refractive index of the barrier 33b. Due to the difference in refractive index between the guide layer 30, the lower clad layer 21, and the upper clad layer 22, the guide layer 30 may function as a waveguide, and the light mode may propagate in the guide layer 30.

Referring to FIG. 4, an optical field may be formed around the guide layer 30. As seen in FIG. 3, this is due to the difference in refractive index between the guide layer 30, the lower clad layer 21, and the upper clad layer 22. The intensity of the light field may be strong in the guide layer 30 and may become weaker toward a lower part of the lower clad layer 21 or toward an upper part of the upper clad layer 22.

The intensities of the light field at the lowermost part of the lower clad layer 21 and the uppermost part of the upper clad layer 22 may be respectively weaker as the thicknesses of the lower clad layer 21 and the upper clad layer 22 in the vertical direction becomes respectively thicker. The thickness of the lower clad layer 21 may be set so that the intensity of the light field at the lowermost part of the lower clad layer 21 is less than or equal to a designated intensity, and the thickness of the upper clad layer 22 may be set so that the intensity of the light field at the uppermost part of the upper clad layer 22 is less than or equal to a designated intensity. As an example, the intensity of the light field at the lowermost part of the lower clad layer 21 and the uppermost part top of the upper clad layer 22 may be about 0 or close to 0.

When the light field feels metal, optical loss may occur. Accordingly, when the lower electrode layer 11 and the upper electrode layer 12 contain metal, light loss may occur as the optical field feels the metal of the lower electrode layer 11 and the upper electrode layer 12. However, if the lower clad layer 21 and the upper clad layer 22 are formed sufficiently thick, the light field felt by the lower electrode layer 11 and the upper electrode layer 12 may be about 0 or close to 0. Thereby, the light field may hardly feel the lower electrode layer 11 and the upper electrode layer 12, and light loss may be minimized.

FIG. 5 is a graph illustrating an overlap factor according to a depth of the crystal hole in the photonic crystal laser device according to an embodiment of the inventive concept.

Referring to FIG. 5, as the depth of the crystal hole CH becomes deeper, the overlap factor may increase. The overlap factor represents the degree to which the optical mode formed in the vertical direction overlaps the crystal hole CH in the vertical direction, and is a numerical value obtained by quantifying the degree to which the optical mode feels the photonic crystal structure. As an example, an overlap factor of about 0.3 means that about 30% of the optical mode feel the crystal hole CH in the vertical direction. In the case where the crystal hole CH extends to the upper guide layer 32 as in an embodiment of the inventive concept, the overlap factor may be larger than when the crystal hole CH penetrates only a portion (e.g., the upper part) of the upper clad layer 22. In other words, compared to the case where the crystal hole CH penetrates only the portion of the upper clad layer 22, in the case where the crystal hole CH extends to the upper guide layer 32, the photonic crystal structure may be better felt by the optical mode.

The depth of the crystal hole CH of the photonic crystal laser device according to an embodiment of the inventive concept may be set so that the overlap factor is about 0.2 or more and about 0.4 or less. In other words, in the photonic crystal laser device according to an embodiment of the inventive concept, about 20% to about 40% of the optical modes may be set so as to feel the crystal hole CH. Thus, compared to the case where the crystal hole CH does not extend to the upper guide layer 32, for example, in the case where the lower end of the crystal hole CH is adjacent to the top surface of the upper guide layer 32 (e.g., when adjacent to the bottom surface of the upper clad layer 22), the overlap factor may be about 0.2 or more. For example, when the lower end of the crystal hole CH is adjacent to the bottom surface of the upper guide layer 32 (e.g., when adjacent to the top surface of the active layer 33), the overlap factor may be about 0.4 or less.

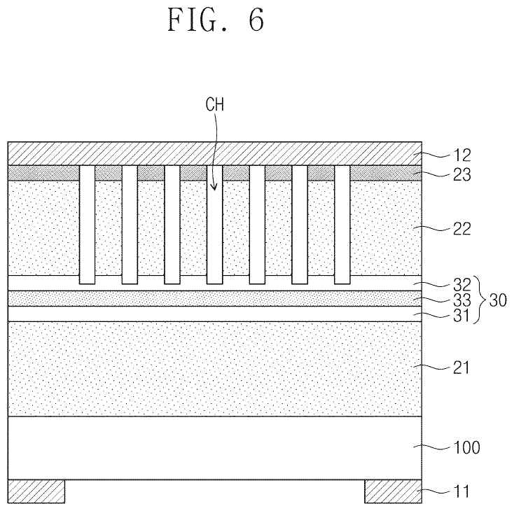

Hereinafter, with reference to FIGS. 6 to 8, embodiments different from FIG. 1 will be described. In order to simplify the description, descriptions of contents that overlaps the contents described above will be omitted and differences therebetween will be mainly described.

FIG. 6 is a cross-sectional view illustrating a photonic crystal laser device according to an embodiment of the inventive concept.

Referring to FIG. 6, the lower electrode layer 11 or the upper electrode layer 12 may vertically partially overlap the crystal hole CH, or may not vertically overlap the crystal hole CH. Accordingly, the laser generated from the photonic crystal laser device may easily escape upward or downward. For convenience of description, the case where the lower electrode layer 11 vertically partially overlaps the crystal hole CH, or does not vertically overlap the crystal hole CH will be described below as an example, but similar features may also appear in the upper electrode layer 12.

As an example, the crystal hole CH may be located in the central region of the photonic crystal laser device. The lower electrode layer 11 may be located at an edge region of the photonic crystal laser device. A plurality of crystal holes CH may be provided, and the lower electrode layer 11 may overlap some of the crystal holes CH, or may not overlap all of the crystal holes CH.

In a planar view, the lower electrode layer 11 may be formed to surround the crystal hole CH and may have various shapes. As an example, the lower electrode layer 11 may have a ring shape, and the crystal hole CH may be surrounded by the ring shape, but is not limited thereto.

When the lower electrode layer 11 vertically partially overlaps or does not vertically overlap the crystal hole CH, preferably, the lower clad layer 21 may be the n-type clad layer. The n-type clad layer, which has relatively high charge mobility, may receive sufficient electrons required for laser oscillation even if it is electrically connected to the electrode layer only in a partial area. Accordingly, despite the structural design for easily extracting the laser, sufficient charges may be provided to the active layer 33. However, an embodiment of the inventive concept is not limited thereto, and the electrode layer adjacent to the p-type clad layer may have the structural characteristics described above.

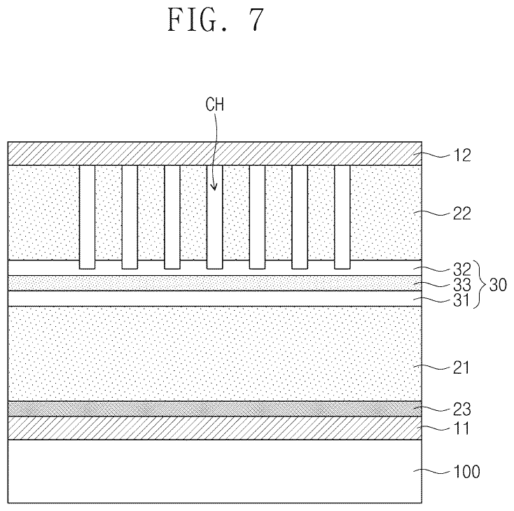

FIG. 7 is a cross-sectional view illustrating a photonic crystal laser device according to an embodiment of the inventive concept.

Referring to FIG. 7, the lower electrode layer 11 may be provided on the top surface of the substrate 100. Accordingly, the substrate 100 may be spaced apart from the lower clad layer 21 with the lower electrode layer 11 interposed therebetween. Unlike FIG. 1, the contact layer 23 is illustrated as interposed between the lower electrode layer 11 and the lower clad layer 21, but is not limited thereto. As an example, differently from what is illustrated, the contact layer 23 may be interposed between the upper electrode layer 12 and the upper clad layer 22 as illustrated in FIG. 1, and the lower electrode layer 11 may be in direct contact with the lower clad layer 21.

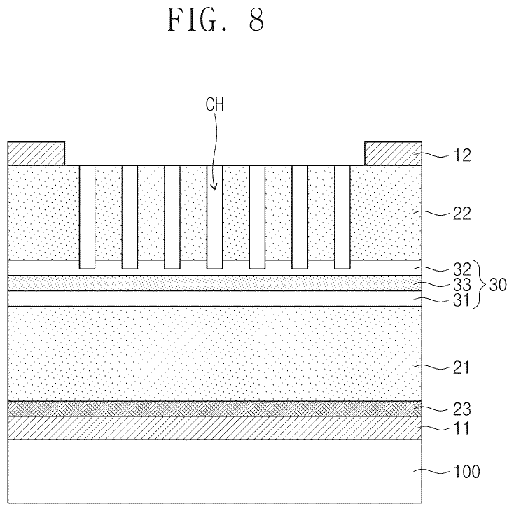

FIG. 8 is a cross-sectional view illustrating a photonic crystal laser device according to an embodiment of the inventive concept.

Referring to FIG. 8, the upper electrode layer 12 may vertically partially overlap the crystal hole CH, or may not vertically overlap the crystal hole CH. The structural characteristics between the upper electrode layer 12 and the crystal hole CH may be similar to the structural characteristics between the lower electrode layer 11 and the crystal hole CH described with reference to FIG. 6.

At the same time, as illustrated in FIG. 7, the lower electrode layer 11 may be provided on the top surface of the substrate 100, and the contact layer 23 may be interposed between the lower electrode layer 11 and the lower clad layer 21. However, an embodiment of the inventive concept is not limited thereto, and although not illustrated, the contact layer 23 may be interposed between the upper electrode layer 12 and the upper clad layer 22.

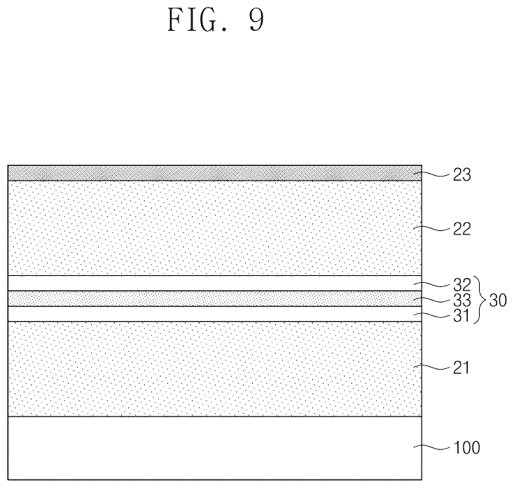

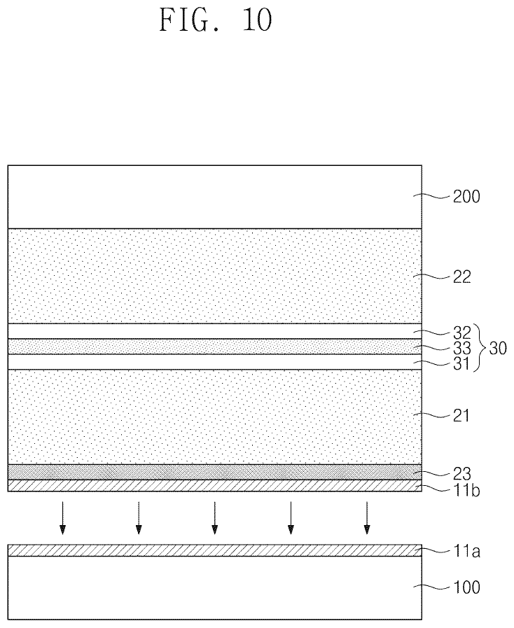

Hereinafter, with reference to FIGS. 9 and 10, respectively, a method for manufacturing a photonic crystal laser device according to an embodiment of the inventive concept will be described. However, the following manufacturing method is an example, and the photonic crystal laser device of the embodiment of the inventive concept described above may be formed through various manufacturing methods that can be modified by those skilled in the art. In order to simplify the description, descriptions of contents that overlaps the contents described above will be omitted and differences therebetween will be mainly described.

FIG. 9 is a cross-sectional view illustrating a method for manufacturing a photonic crystal laser device according to an embodiment of the inventive concept.

Referring to FIG. 9, the lower clad layer 21, the guide layer 30, and the upper clad layer 22 may be formed on the substrate 100. For example, forming the lower clad layer 21, the guide layer 30, and the upper clad layer 22 may include sequentially stacking the layers through a deposition process. As an example, the deposition process may include performing one or more of deposition processes such as physical vapor deposition (PVD), chemical vapor deposition (CVD), and atomic layer deposition (ALD). As an example, forming the guide layer 30 may include sequentially depositing the lower guide layer 31, the active layer 33, and the upper guide layer 32.

As an example, the contact layer 23 may be further formed. The contact layer 23 may be formed below the lower clad layer 21 or above the upper clad layer 22. For example, when the contact layer 23 is formed below the lower clad layer 21, the contact layer 23 may be formed before the lower clad layer 21 is formed. For example, when the contact layer 23 is formed above the upper clad layer 22, the contact layer 23 may be formed after the upper clad layer 22 is formed.

Referring again to FIG. 1, the crystal hole CH may be formed to penetrate the upper part of the previously formed stacked structure. The crystal hole CH may be formed to extend from the top surface of the upper clad layer 22 to the inside of the upper guide layer 32. As an example, the lower end of the crystal hole CH may be formed at a height lower than the top surface of the upper clad layer 22 and higher than or the same as the top surface of the active layer 33.

As an example, forming the crystal hole CH may include sequentially performing a lithography process and an etching process. Through the lithography process, the two-dimensional photonic crystal pattern formed by the crystal holes CH may be defined, and through the etching process, the crystal holes CH may be formed on the upper part of the stacked structure. As an example, the etching process may be a dry etching process.

The lower electrode layer 11 and the upper electrode layer 12 may be formed at various times as the manufacturing process described above is conducted. As an example, the upper electrode layer 12 may be formed to cover the upper clad layer 22 and the crystal hole CH after the crystal hole CH is formed. Through this, the upper electrode layer 12 of the same or similar form as that described with reference to FIG. 1 may be formed. As another example, the upper electrode layer 12 may be formed to cover the upper clad layer 22 and the crystal hole CH, and the lithography and etching processes for the upper electrode layer 12 may be further conducted. Through this, the upper electrode layer 12 of the same or similar form as that described with reference to FIG. 8 may be formed. As another example, the upper electrode layer 12 may be formed before the crystal hole CH is formed, and the lithography and etching processes for the upper electrode layer 12 may be further conducted. Thereafter, the crystal hole CH may be formed in the region where the upper electrode layer 12 is etched, and through this, the upper electrode layer 12 of the same or similar form as described with reference to FIG. 8 may be formed. However, this is an example, and the embodiment of the inventive concept of the is not limited thereto.

FIG. 10 is a cross-sectional view illustrating a method for manufacturing a photonic crystal laser device according to an embodiment of the inventive concept.

Referring to FIG. 10, a first lower electrode layer 11a may be formed on the substrate 100. Separately, an auxiliary substrate 200 may be provided, and the auxiliary substrate 200 may be a substrate for depositing each layer of the photonic crystal laser device. The upper clad layer 22, the guide layer 30, the lower clad layer 21, and a second lower electrode layer 11b may be formed on the auxiliary substrate 200. As an example, forming the upper clad layer 22, the guide layer 30, the lower clad layer 21, and the second lower electrode layer 11b may include sequentially stacking the layers through the deposition process. As an example, the contact layer 23 may be further formed between the lower clad layer 21 and the second lower electrode layer 11b, but is not limited thereto.

Thereafter, the stacked structure on the auxiliary substrate 200 may be bonded to the substrate 100. As an example, the bonding process may include turning the stacked structure upside down to position the second lower electrode layer 11b underneath, and bonding the stacked structure, which is turned upside down, to the first lower electrode layer 11a on the substrate 100. Through the bonding process, the first lower electrode layer 11a and the second lower electrode layer 11b may be joined to each other, and the lower electrode layer 11 may be formed with the electrode layers.

Referring again to FIG. 1, the auxiliary substrate 200 may be removed. The auxiliary substrate 200 may be removed through various methods. As an example, the auxiliary substrate 200 may be removed through a chemical mechanical polishing (CMP) and/or an etching process (e.g., a wet etching process) for the auxiliary substrate 200. As another example, the auxiliary substrate 200 may be removed by separating removing the auxiliary substrate 200 from the upper clad layer 22.

Thereafter, the crystal hole CH and the upper electrode layer 12 may be formed. Forming the crystal hole CH and the upper electrode layer 12 may be formed through the same or similar manufacturing method as in the formation of the crystal hole CH and the upper electrode layer 12 described with reference to FIGS. 1 and 9.

As described above, although embodiments of the inventive concept have been described with reference to the attached drawings, a person skilled in the art to which an embodiment of the inventive concept pertains will understand that the embodiment of the inventive concept may be implemented in other specific forms without changing its technical idea or essential features. Therefore, the embodiments described above should be understood as illustrative in all respects and not restrictive.

According to an embodiment of the inventive concept, by forming the crystal hole at an appropriate depth, the optical mode may be stably formed, and this vertical optical mode may effectively feel the two-dimensional photonic crystal pattern, and at the same time, the decrease in light emission efficiency may be minimized by not touching the active layer. As a result, the laser oscillation characteristics of the photonic crystal laser device may be improved.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A photonic crystal laser device comprising:
a lower electrode layer on a top surface or bottom surface of a substrate;
a guide layer on the lower electrode layer;
an upper electrode layer on the guide layer;
a lower clad layer between the lower electrode layer and the guide layer; and
an upper clad layer between the guide layer and the upper electrode layer, wherein
the guide layer includes an active layer therein,
a crystal hole is provided that penetrates the upper clad layer in a vertical direction and extends toward the guide layer, and
a lower end of the crystal hole is defined to be at a height higher than or at the same height as a top surface of the active layer.

2. The device of claim 1, wherein.
the guide layer further includes a lower guide layer between the active layer and the lower clad layer, and an upper guide layer between the active layer and the upper clad layer, and
the lower end of the crystal hole is defined to be at a height lower than a top surface of the upper clad layer and higher than or at the same height as the top surface of the active layer.

3. The device of claim 1, wherein
the lower clad layer is an n-type clad layer, and
the upper clad layer is a p-type clad layer.

4. The device of claim 1, wherein
the lower clad layer is a p-type clad layer, and
the upper clad layer is an n-type clad layer.

5. The device of claim 1, wherein.
a refractive index of the guide layer is higher than a refractive index of each of the lower clad layer and the upper clad layer.

6. The device of claim 1, wherein
the crystal hole is located in a central region of the photonic crystal laser device.

7. The device of claim 1, wherein
the lower electrode layer or the upper electrode layer is located at an edge region of the photonic crystal laser device.

8. The device of claim 1, wherein
the lower electrode layer or the upper electrode layer does not vertically overlap the crystal hole.

9. The device of claim 1, wherein.
a thickness of the lower clad layer in the vertical direction is set so that an intensity of a light field at a lowermost part of the lower clad layer is less than or equal to a designated intensity, and
a thickness of the upper clad layer in the vertical direction is set so that an intensity of a light field at an uppermost part of the upper clad layer is less than or equal to a designated intensity.

10. The device of claim 1, wherein
the crystal hole includes a plurality of crystal holes, and
the plurality of crystal holes form a photonic crystal pattern.

11. The device of claim 10, wherein
the plurality of crystal holes form a random structure.

12. The device of claim 1, further comprising:
a low refractive index material filling the crystal hole.

13. The device of claim 1, further comprising:
a contact layer interposed between the lower electrode layer and the lower clad layer, or between the upper electrode layer and the upper clad layer.

14. The device of claim 13, wherein
the contact layer is interposed between the upper electrode layer and the upper clad layer, and
the crystal hole further extends from the upper clad layer to a top surface of the contact layer.

15. A method for manufacturing a photonic crystal laser, the method comprising:
sequentially forming a lower clad layer, a guide layer, and an upper clad layer on a substrate; and
forming a crystal hole that penetrates the upper clad layer in a vertical direction and extends toward the guide layer, wherein
the guide layer includes an active layer therein, and
a lower end of the crystal hole is formed at a height higher than or at the same height as a top surface of the active layer.

16. The method of claim 15, further comprising:
forming an upper electrode layer on the upper clad layer before or after forming the crystal hole.

17. The method of claim 15, wherein
the guide layer further includes a lower guide layer between the active layer and the lower clad layer, and an upper guide layer between the active layer and the upper clad layer, and
the lower end of the crystal hole is formed at a height lower than a top surface of the upper clad layer and higher than or at the same height as the top surface of the active layer.

18. A method for manufacturing a photonic crystal laser, the method comprising:
sequentially stacking an upper clad layer, a guide layer, and a lower clad layer on an auxiliary substrate;
bonding a stacked structure to a substrate by turning the stacked structure on the auxiliary substrate upside down;
removing the auxiliary substrate; and
forming a crystal hole that penetrates the upper clad layer in a vertical direction and extends toward the guide layer, wherein
the guide layer includes an active layer therein, and
a lower end of the crystal hole is formed at a height higher than or at the same height as a top surface of the active layer.

19. The method of claim 18, further comprising:
prior to the bonding,
forming a first lower electrode layer on the substrate; and
forming a second lower electrode layer on the lower clad layer, wherein
a lower electrode layer in which the first lower electrode layer and the second lower electrode layer are combined is formed through the bonding.

20. The method of claim 18, wherein
the guide layer further includes a lower guide layer between the active layer and the lower clad layer, and an upper guide layer between the active layer and the upper clad layer, and
the lower end of the crystal hole is formed at a height lower than a top surface of the upper clad layer and higher than or at the same height as the top surface of the active layer.
